(19) United States
(12) Patent Application Publication
(10) Pub. No.: US 2023/0268163 A1
(43) Pub. Date: Aug. 24, 2023

(54) SEMICONDUCTOR MANUFACTURING APPARATUS

(71) Applicant: Kioxia Corporation, Tokyo (JP)

(72) Inventor: Makoto KUBO, Kuwana Mie (JP)

(73) Assignee: Kioxia Corporation, Tokyo (JP)

(21) Appl. No.: 17/842,551

(22) Filed: Jun. 16, 2022

(30) Foreign Application Priority Data
Feb. 18, 2022 (JP) 2022-024291

(51) Int. Cl. H01J 37/32; C23C 16/458; C23C 16/34; C23C 16/40; C23C 16/50; C23C 16/455

(52) U.S. Cl. CPC H01J 37/32449; H01J 37/32541; H01J 37/32568; C23C 16/4583; C23C 16/345; C23C 16/402; C23C 16/50; C23C 16/45563; H01J 2237/3321

(57) ABSTRACT

An apparatus includes a container. A holder is in the container and holds a substrate. A gas-introducer is on a side of a first-face of the substrate and introduces a process gas into the container. A first gas supply plate is between the substrate and the gas introducing part and has first-holes allowing the process gas to pass. A first-electrode is between the substrate and the first gas supply plate and has second-holes supplying the process gas to the first-face of the substrate. A second-electrode is provided on a side of a second-face of the substrate and applies an electric field to the process gas between the first and second-electrodes. Partitions are provided between the first-electrode and the first gas supply plate, extend substantially linearly in a first direction substantially parallel to the first-face, and divide a space between the first-electrode and the first gas supply plate into regions.

### CROSS REFERENCE TO RELATED APPLICATIONS

This application is based upon and claims the benefit of priority from the prior Japanese Patent Application No. 2022-024291, filed on Feb. 18, 2022, the entire contents of which are incorporated herein by reference.

### FIELD

The embodiments of the present invention relate to a semiconductor manufacturing apparatus.

### BACKGROUND

Some of semiconductor storage devices such as a NAND flash memory have a three-dimensional memory cell array in which a plurality of memory cells are three-dimensionally arrayed. A semiconductor substrate having such a three-dimensional memory cell array sometimes warps depending on the extending direction of word lines. There is a risk that warp of the semiconductor substrate affects the yield ratio and causes a problem in transporting of the semiconductor substrate in a semiconductor manufacturing process.

### BRIEF DESCRIPTION OF THE DRAWINGS

FIG. 1 is a schematic diagram illustrating a configuration example of a semiconductor manufacturing apparatus according to a first embodiment;

FIG. 2 is a plan view illustrating a configuration example of the lower electrode;

FIG. 3 is a sectional view illustrating the configuration example of the lower electrode;

FIG. 4 is a plan view illustrating a configuration example of the second gas dispersing plate;

FIG. 5 is a plan view illustrating a configuration example of the first gas dispersing plate;

FIG. 6 is a sectional view illustrating a configuration example of the first gas dispersing plate, the second gas dispersing plate, the gas introducing part, and the pipes;

FIG. 7 is a conceptual diagram illustrating a relation between warp of a substrate and word lines;

FIG. 8 is a graph illustrating the warp amount of the substrate when the material film is formed on the first face of the substrate;

FIGS. 9A and 9B are conceptual diagrams illustrating warp of the substrate when the material film is formed on the first face of the substrate;

FIG. 10 is a plan view illustrating a configuration example of the lower electrode according to a second embodiment;

FIG. 11 is a sectional view illustrating the configuration example of the lower electrode according to the second embodiment;

FIG. 12 is a plan view illustrating a configuration example of the second gas dispersing plate according to the second embodiment;

FIG. 13 is a plan view illustrating a configuration example of the first gas dispersing plate according to the second embodiment;

FIG. 14 is a plan view illustrating a configuration example of the lower electrode according to a third embodiment;

FIG. 15 is a sectional view illustrating the configuration example of the lower electrode according to the third embodiment;

FIG. 16 is a plan view illustrating a configuration example of the lower electrode according to a fourth embodiment;

FIG. 17 is a plan view illustrating a configuration example of the mask part attached to the lower electrode;

FIG. 18 is a sectional view illustrating a configuration example of the lower electrode and the mask part;

FIGS. 19 and 20 are diagrams illustrating a state in which the mask part opens some of the holes of the lower electrode in a central portion;

FIGS. 21 and 22 are diagrams illustrating a state in which the mask part opens some of the holes of the lower electrode in a central portion;

FIGS. 23 and 24 are diagrams illustrating a state in which the mask part opens all the holes of the lower electrode;

FIG. 25 is a plan view illustrating a configuration example of the lower electrode according to a fifth embodiment;

FIG. 26 is a plan view illustrating a configuration example of the mask part attached to the lower electrode;

FIG. 27 is a sectional view illustrating a configuration example of the lower electrode and the mask part;

FIGS. 28 and 29 are diagrams illustrating a state in which the mask part opens some of the holes of the lower electrode; and

FIGS. 30 and 31 are diagrams illustrating a state in which the mask part opens all the holes of the lower electrode.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A semiconductor manufacturing apparatus according to the present embodiment comprises a processing container. A holder is provided in the processing container and capable of holding a substrate. A gas introducing part is provided on a side of a first face of the substrate and configured to introduce a process gas into the processing container. A first gas supply plate is provided between the substrate and the gas introducing part and has a plurality of first holes allowing the process gas to pass. A first electrode is provided between the substrate and the first gas supply plate and has a plurality of second holes supplying the process gas to the first face of the substrate. A second electrode is provided on a side of a second face of the substrate opposite to the first face and applies an electric field to the process gas between the first and second electrodes. A plurality of partitions are provided between the first electrode and the first gas supply plate, extend substantially linearly in a first direction substantially parallel to the first face, and divide a space between the first electrode and the first gas supply plate into a plurality of regions.

### (First Embodiment)

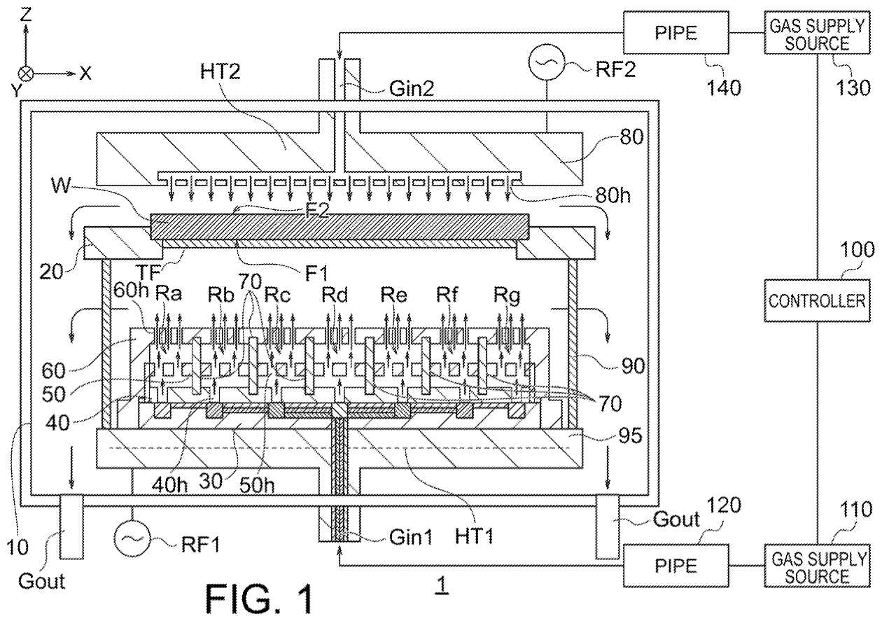

FIG. 1 is a schematic diagram illustrating a configuration example of a semiconductor manufacturing apparatus 1 according to a first embodiment. The semiconductor manufacturing apparatus 1 (hereinafter, also simply “apparatus 1”) is, for example, a CVD (Chemical Vapor Deposition) apparatus that forms a material film TF on a substrate W.

The apparatus 1 includes a chamber 10, a carrier ring 20, a gas introducing part 30, a first gas dispersing plate 40, a second gas dispersing plate 50, a lower electrode 60, a plurality of partition plates 70, an upper electrode 80, support posts 90, a controller 100, gas supply sources 110 and 130, and pipes 120 and 140.

The chamber 10 can accommodate a substrate W and the inner portion thereof can be depressurized. A film forming process is performed for the substrate W in the inner portion of the chamber 10. For example, a material having resistance to heat, pressure, and corrosion such as stainless steel is used for the chamber 10.

The carrier ring 20 is a holder that is capable of holding the substrate W in the chamber 10. The carrier ring 20 has, for example, a circular ring shape and supports the end portion of the substrate W at a counterbore formed on the inner periphery of the carrier ring 20. A central portion of the carrier ring 20 is open to enable a material film TF to be formed on a first face (a back surface) F1 of the substrate W. For example, any of materials such as aluminum, stainless steel, and ceramics is used for the carrier ring 20. The substrate W has the first face F1 on which the material film TF is to be formed, and a second face F2 on the opposite side to the first face F1. The substrate W is, for example, a semiconductor substrate such as a silicon substrate. Semiconductor elements such as a three-dimensional memory cell array are formed on the second face F2 of the substrate W. The first face F1 of the substrate W is the back surface of the substrate W and no semiconductor element is formed thereon.

The gas introducing part 30 introduces a process gas branched off by the pipes 120 from the side of the first face F1 of the substrate W into the chamber 10 through a gas introducing pipe Gin1. The gas introducing part 30 supplies the process gas to the first gas dispersing plate 40. For example, a material having resistance to heat and corrosion, such as stainless steel or ceramics, is used for the gas introducing part 30.

The gas introducing pipe Gin1 guides the process gas branched off by the pipes 120 to be supplied to associated regions between the first gas dispersing plate 40 and the lower electrode 60.

The first gas dispersing plate 40 is provided between the substrate W and the gas introducing part 30 and has a plurality of holes 40h that allow the process gas to pass. One or plural holes 40h are provided for each of a plurality of regions Ra to Rg that are separated by the partition plates 70 between the lower electrode 60 and the first gas dispersing plate 40. The holes 40h communicate from the gas introducing pipe Gin1 to any of the regions Ra to Rg and introduce the process gas from the gas introducing pipe Gin1 to the associated regions Ra to Rg, respectively. At this time, the holes 40h function to disperse the process gas in the associated regions Ra to Rg, respectively. For example, any of materials such as aluminum, stainless steel, and ceramics is used for the first gas dispersing plate 40.

The second gas dispersing plate 50 is provided between the first gas dispersing plate 40 and the lower electrode 60 and has a plurality of holes 50h that allow the process gas to pass. One or plural holes 50h are provided for each of the regions Ra to Rg. The holes 50h function to disperse the process gas from the first gas dispersing plate 40 in inner portions of the associated regions Ra to Rg, respectively. The second gas dispersing plate 50 is not necessarily provided and may be omitted. In this case, the process gas introduced from the first gas dispersing plate 40 to the regions Ra to Rg is supplied from the lower electrode 60 to the substrate W without passing through the second gas dispersing plate 50. For example, any of materials such as aluminum, stainless steel, and ceramics is used for the second gas dispersing plate 50.

The lower electrode 60 is provided between the substrate W and the first and second gas dispersing plates 40 and 50 and has a plurality of holes 60h that supply the process gas to the first face F1 of the substrate W. One or plural holes 60h are provided for each of the regions Ra to Rg. For example, the holes 60h are arrayed substantially uniformly in a matrix in each of the regions Ra to Rg of the lower electrode 60. The holes 60h supply the process gas supplied from the first and second gas dispersing plates 40 and 50 from the associated regions Ra to Rg to the first face F1 of the substrate W in the chamber 10. The distance between the first face F1 of the substrate W and the lower electrode 60 is relatively short and the process gas is supplied to regions of the first face F1 of the substrate W respectively facing the holes 60h. It is preferable that the numbers of the holes 40h, 50h, and 60h meet a relation: the number of the holes 40h<the number of the holes 50h<the number of the holes 60h to dispersedly introduce the process gas into the chamber 10. For example, any of materials such as aluminum, stainless steel, and ceramics is used for the lower electrode 60.

The lower electrode 60 is connected to a high-frequency power source RF1 and receives power from the high-frequency power source RF1. Accordingly, the lower electrode 60 is used to apply an electric field to the process gas located between the substrate W and the lower electrode 60 and ionize the process gas to generate plasma.

The partition plates 70 are provided between the lower electrode 60 and the first gas dispersing plate 40 and divide a space between the lower electrode 60 and the first gas dispersing plate 40 into the regions Ra to Rg. Lower ends of the partition plates 70 are in contact with the first gas dispersing plate 40 and are fitted in trenches formed on the first gas dispersing plate 40. Upper ends of the partition plates 70 are in contact with the lower electrode 60 and are fitted in trenches formed on the lower electrode 60. Therefore, the partition plates 70 extend from the lower electrode 60 to the first gas dispersing plate 40 in a supply direction (a Z direction) of the process gas and separate the process gases in the regions Ra to Rg from each other. The partition plates 70 also extend substantially linearly in a Y direction substantially parallel to the first face F1 of the substrate W and extend substantially in parallel to each other in the Y direction. Accordingly, the partition plates 70 suppress direct diffusion of the process gases among the regions Ra to Rg and almost airtightly separate the process gases from each other. Although the regions Ra to Rg indirectly communicate with each other through the holes 60h, each of the regions Ra to Rg is in a substantially airtight state during processing because the holes 60h of the lower electrode 60 jet the process gas toward the substrate W. For example, any of materials such as aluminum, stainless steel, and ceramics is used for the partition plates 70.

The upper electrode 80 is provided on the side of the second face F2 of the substrate W opposite to the first face F1. The upper electrode 80 is connected to a high-frequency power source RF2 and receives power from the high-frequency power source RF2. The lower electrode 60 and the upper electrode 80 apply an electric field to the process gas between the substrate W and the lower electrode 60 and ionize the process gas to be brought to a plasma state. This enables the material film TF that is made from the process gas to be formed on the first face F1 of the substrate W.

The upper electrode 80 includes a gas introducing pipe Gin2 and a plurality of holes 80h. The gas introducing pipe Gin2 introduces an inert gas branched off by the pipe 140 into the chamber 10. The holes 80h are formed on a face of the upper electrode 80 facing the second face F2 of the substrate W and supply the inert gas to the second face F2 of the substrate W. During processing, the upper electrode 80 supplies the inert gas from the holes 80h to the second face F2 of the substrate W and suppresses the material film TF that is made from the process gas from being formed on the second face F2 of the substrate W. The inert gas may be, for example, helium, nitrogen, or argon. For example, any of materials such as aluminum, stainless steel, and ceramics is used for the upper electrode 80.

A heater HT1 is provided below the gas introducing part 30 and the first and second gas dispersing plates 40 and 50. For example, the heater HT1 is provided inside a base 95 through which the gas introducing pipe Gin1 penetrates. A heater HT2 is provided in the upper electrode 80. The heaters HT1 and HT2 are provided to heat the substrate W to a predetermined temperature.

The support posts 90 are provided between the base 95 and the carrier ring 20 and support the carrier ring 20.

The controller 100 controls the gas supply sources 110 and 130 to control the flow rates and/or the introducing times of the process gas and the inert gas. For example, the controller 100 controls the flow rate or the introducing time of the process gas to be introduced into each of the regions Ra to Rg. This enables the thicknesses of the material film TF in regions of the first face F1 of the substrate W respectively corresponding to the regions Ra to Rg to be different from each other. That is, the controller 100 can control the film thickness of the material film TF in the first face F1 of the substrate W by changing the supply amounts of the process gas to be introduced in the regions Ra to Rg, respectively.

The gas supply source 110 supplies the process gas to the gas introducing pipe Gin1 through the pipes 120. The gas supply source 130 supplies the inert gas to the gas introducing pipe Gin2 through the pipe 140

The pipes 120 may be, for example, a manifold configured to be capable of carrying the process gas at certain flow rates to the regions Ra to Rg, respectively. The pipe 140 may be a manifold configured to be capable of carrying the inert gas at a certain flow rate to the gas introducing pipe Gin2.

The controller 100 can control the flow rate and the introducing time of the process gas to each of the regions Ra to Rg by controlling the gas supply source 110 and the pipes 120. The controller 100 can control the flow rate and the introducing time of the inert gas to the gas introducing pipe Gin2 by controlling the gas supply source 130 and the pipe 140.

The process gas and the inert gas introduced into the chamber 10 are discharged from a gas outlet Gout after being used to form the material film TF.

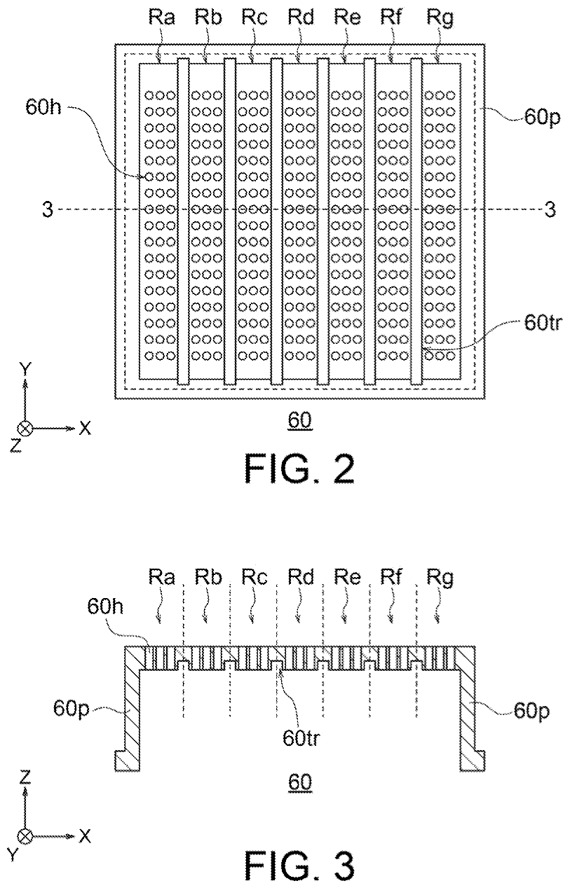

FIG. 2 is a plan view illustrating a configuration example of the lower electrode 60. FIG. 3 is a sectional view illustrating the configuration example of the lower electrode 60. FIG. 3 illustrates a cross section along a line 3-3 in FIG. 2.

The lower electrode 60 has a substantially quadrangular shape having four sides equal to or larger than the diameter of the substrate W as viewed from a direction (the Z direction) perpendicular to the first face F1 of the substrate W. Therefore, when the substrate W is mounted on the carrier ring 20, the lower electrode 60 overlaps with the substrate W and the outer edge of the lower electrode 60 is positioned on an outer side than the outer edge of the substrate W as viewed from the Z direction. Accordingly, the holes 60h of the lower electrodes 60 can be arranged substantially uniformly for all over the substrate W.

The lower electrode 60 has a plurality of trenches 60tr in which the partition plates 70 are respectively fitted. The trenches 60tr are provided on a face of the lower electrode 60, facing the first or second gas dispersing plate 40 or 50 and are provided to extend substantially linearly in the Y direction similarly to the partition plates 70. Therefore, the trenches 60tr are located between adjacent ones of the regions Ra to Rg. The holes 60h are arranged substantially uniformly in each of the regions Ra to Rg. This enables the lower electrode 60 to supply the process gas to each of regions of the first face F1 of the substrate W corresponding to the regions Ra to Rg, respectively. As a result, the material film TF having different thicknesses according to the regions Ra to Rg can be formed on the first face F1 of the substrate W.

A support 60p is provided at the outer edge of the lower electrode 60 and positions the lower electrode 60 between the first and second gas dispersing plates 40 and 50 and the substrate W. The support 60p forms a space between the lower electrode 60 and the first gas dispersing plate 40. The support 60p may be provided along the entire outer edge of the lower electrode 60. Alternatively, the support 60p may be provided partially at locations where the support 60p may stably support the lower electrode 60 (for example, only at four corners). The support 60p may be formed integrally with a portion where the holes 60h of the lower electrode 60 are arranged.

FIG. 4 is a plan view illustrating a configuration example of the second gas dispersing plate 50.

The second gas dispersing plate 50 has a substantially quadrangular shape having four sides equal to or larger than the diameter of the substrate W as viewed from the direction (the Z direction) perpendicular to the first face F1 of the substrate W, similarly to the lower electrode 60. Therefore, when the substrate W is mounted on the carrier ring 20, the second gas dispersing plate 50 overlaps with the substrate W and the outer edge of the second gas dispersing plate 50 is positioned on an outer side than the outer edge of the substrate W as viewed from the Z direction. Accordingly, the holes 50h of the second gas dispersing plate 50 are arranged dispersedly all over the substrate W.

The second gas dispersing plate 50 has a plurality of through slots 50v in which the partition plates 70 are respectively fitted. The through slots 50v are provided on a face of the second gas dispersing plate 50, facing the first gas dispersing plate 40 or the lower electrode 60 and are provided to extend substantially linearly in the Y direction, similarly to the partition plates 70. Therefore, the through slots 50v are located between adjacent ones of the regions Ra to Rg. The holes 50h are arranged substantially uniformly in each of the regions Ra to Rg and are arranged not to be aligned with the holes 40h of the first gas dispersing plate 40 in a planar view as viewed from the Z direction. Accordingly, the second gas dispersing plate 50 can dispersedly feed out the process gas from the first gas dispersing plate 40 toward the lower electrode 60 in each of the regions Ra to Rg.

Due to provision of the partition plates 70 penetrating through the second gas dispersing plate 50 to the first gas dispersing plate 40, the regions Ra to Rg guide the associated process gases to the lower electrode 60 without mixing the process gases with each other while maintaining the supply amounts of the process gases respectively supplied thereto from the gas introducing part 30. Therefore, the lower electrode 60 can supply different supply amounts of the process gas to the regions of the first face F1 of the substrate W corresponding to the regions Ra to Rg, respectively.

A support 50p is provided at the outer edge of the second gas dispersing plate 50 and positions the second gas dispersing plate 50 between the first gas dispersing plate 40 and the lower electrode 60. The support 50p forms a space between the second gas dispersing plate 50 and the first gas dispersing plate 40 and between the second gas dispersing plate 50 and the lower electrode 60. The support 50p may be provided along the entire outer edge of the second gas dispersing plate 50. Alternatively, the support 50p may be provided partially at locations where the support 50p may stably support the second gas dispersing plate 50 (for example, only at four corners). The support 50p may be formed integrally with a portion where the holes 50h of the second gas dispersing plate 50 are arranged.

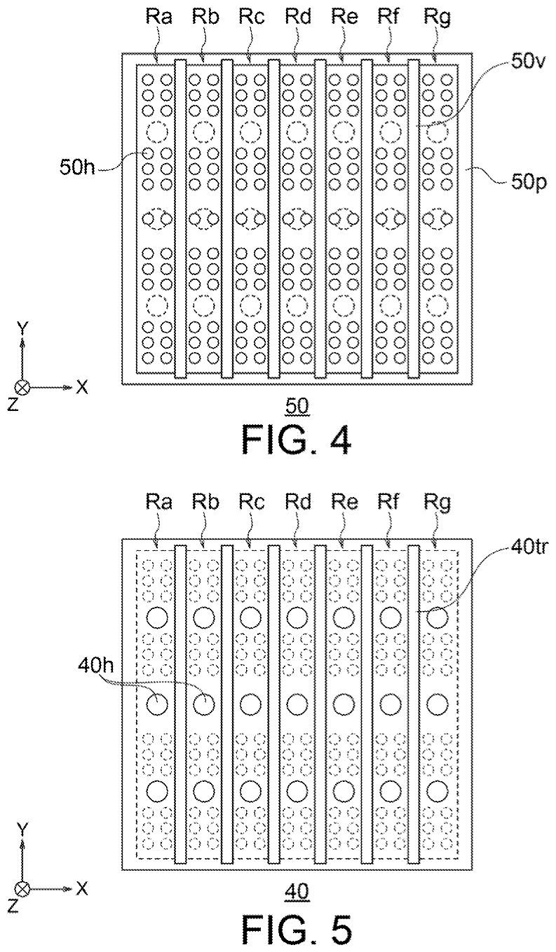

FIG. 5 is a plan view illustrating a configuration example of the first gas dispersing plate 40.

The first gas dispersing plate 40 has a substantially quadrangular shape having four sides equal to or larger than the diameter of the substrate W as viewed from the direction (the Z direction) perpendicular to the first face F1 of the substrate W, similarly to the lower electrode 60. Therefore, when the substrate W is mounted on the carrier ring 20, the first gas dispersing plate 40 overlaps with the substrate W and the outer edge of the first gas dispersing plate 40 is positioned on an outer side than the outer edge of the substrate W as viewed from the Z direction. Accordingly, the holes 40h of the first gas dispersing plate 40 are dispersedly arranged all over the substrate W.

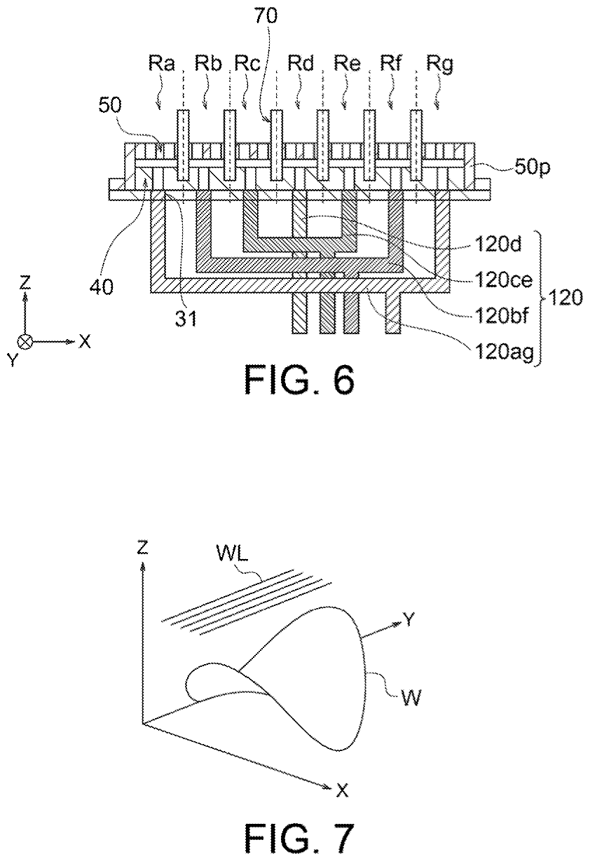

The first gas dispersing plate 40 has a plurality of trenches 40tr in which the partition plates 70 are respectively fitted. The trenches 40tr are provided on a face of the first gas dispersing plate 40, facing the lower electrode 60 or the second gas dispersing plate 50 and are provided to extend substantially linearly in the Y direction, similarly to the partition plates 70. The trenches 40tr are located between adjacent ones of the regions Ra to Rg to enable the partition plates 70 to separate the regions Ra to Rg. The holes 40h are arranged substantially uniformly in each of the regions Ra to Rg and are provided to correspond to gas inlets 31 of the gas introducing part 30 in FIG. 6, respectively, in a planar view as viewed from the Z direction. The gas inlets 31 are provided to correspond to the regions Ra to Rg and introduce the process gas to the associated regions Ra to Rg, respectively. Accordingly, the first gas dispersing plate 40 can feed out the process gas from the gas introducing part 30 to each of the regions Ra to Rg.

FIG. 6 is a sectional view illustrating a configuration example of the first gas dispersing plate 40, the second gas dispersing plate 50, the gas introducing part 30, and the pipes 120. The pipes 120 are connected to different gas inlets 31, respectively, depending on distances from a central portion of the substrate W of regions from the region Rd in the central portion of the substrate W to the regions Ra and Rg in end portions of the substrate W. For example, the pipes 120 include pipes 120d, 120ce, 120bf, and 120ag. The pipe 120d is connected to a gas inlet 31 corresponding to the region Rd in the central portion of the substrate W and introduces the process gas to the region Rd. The pipe 120ce is connected to gas inlets 31 corresponding to the regions Rc and Re adjacent to the region Rd on the both sides, respectively, and introduces the process gas to the regions Rc and Re. The pipe 120bf is connected to gas inlets 31 corresponding to the region Rf adjacent to the region Re and the region Rb adjacent to the region Rc, respectively, and introduces the process gas to the regions Rf and Rb. The pipe 120ag is connected to gas inlets 31 corresponding to the region Rg adjacent to the region Rf and the region Ra adjacent to the region Rb, respectively, and introduces the process gas to the regions Rg and Ra. The controller 100 can supply the process gas of different flow rates to the region Rd, the regions Rc and Re, the regions Rb and Rf, and the regions Ra and Rg through the pipes 120d, 120ce, 120bf, and 120ag, respectively. Alternatively, the controller 100 can supply the process gas to the region Rd, the regions Rc and Re, the regions Rb and Rf, and the regions Ra and Rg for different time periods, respectively. Accordingly, the controller 100, the gas supply source 110, and the pipes 120 can introduce different supply amounts of the process gas to the regions Ra to Rg, respectively. The configuration of the pipes 120 is not particularly limited and any configuration can be applied thereto. For example, the process gas may be separately supplied to each of the regions Ra to Rg. In this case, the supply amounts of the process gas are enabled to differ among the regions Ra to Rg.

With the configuration described above, the process gas from the gas inlets 31 of the gas introducing part 30 are respectively introduced to the regions Ra to Rg through the holes 40h of the first gas dispersing plate 40. In the regions Ra to Rg, the process gas is dispersed by the first and second gas dispersing plates 40 and 50. Further, the process gas introduced into each of the regions Ra to Rg is further supplied to the first face F1 of the substrate W through the holes 60h of the lower electrode 60. Since the regions Ra to Rg are separated by the partition plates 70, the process gases in the regions Ra to Rg are not mixed in the regions Ra to Rg and are supplied from the lower electrode 60 to the associated regions of the substrate W, respectively. Therefore, the controller 100 can control each of the supply amounts of the process gas to be supplied from the regions Ra to Rg to the substrate W by controlling the flow rate or the introducing time of the process gas to be introduced into each of the regions Ra to Rg.

Warp of the substrate W is described here.

FIG. 7 is a conceptual diagram illustrating a relation between warp of a substrate W and word lines WL. In a three-dimensional memory cell array, the word lines WL are stacked in the Z direction and are electrically isolated from each other by slits (not illustrated) extending in the Z direction. When the slits extend in the Y direction in a planar view as viewed from the Z direction, the word lines WL also extend in the Y direction as illustrated in FIG. 7.

The warp of the substrate W depends on the extending direction of the word lines WL. For example, when the extending direction of the word lines WL is the Y direction, the substrate W is dented in a −Z direction at a central portion in the Y direction and rises in a +Z direction at both end portions as illustrated in FIG. 7. That is, the substrate W warps in a substantially U shape (a bowl shape) in a cross section in the Y direction. There is a risk that such warp of the substrate W interferes transporting of the substrate W in a semiconductor manufacturing process. Further, warp of the substrate W causes a reduction of the yield ratio. Therefore, in the present embodiment, the material film TF is formed on the back surface of the substrate W to correct the warp of the substrate W caused by the word lines WL.

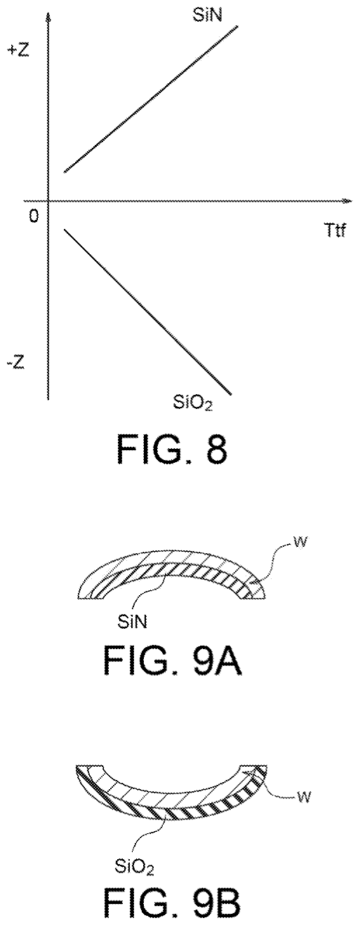

FIG. 8 is a graph illustrating the warp amount of the substrate W when the material film TF is formed on the first face F1 of the substrate W. The horizontal axis represents a thickness Ttf of the material film TF. The vertical axis represents a warp amount of the substrate W resulting from the material film TF. The warp amount of the substrate W indicates the location of a central portion in the Z direction with respect to an end portion of the substrate W. Therefore, the +Z direction in this graph indicates that the central portion of the substrate W is protruded relative to the end portion to be in a convex state in a lobe shape. The −Z direction indicates that the central portion of the substrate W is recessed relative to the end portion to be in a concave state in a bowl shape. FIGS. 9A and 9B are conceptual diagrams illustrating warp of the substrate W when the material film TF is formed on the first face F1 of the substrate W.

When the material film TF is a silicon nitride film, the substrate W has the central portion protruded relative to the end portion to warp in a lobe shape as illustrated in FIG. 9A. When the film thickness Ttf of the material film TF (the silicon nitride film) is increased, the warp amount of the substrate W increases as indicated in FIG. 8.

When the material film TF is a silicon dioxide film, the substrate W has the central portion recessed relative to the end portion to warp in a bowl shape as illustrated in FIG. 9B. When the film thickness Ttf of the material film TF (the silicon dioxide film) is increased, the warp amount of the substrate W increases as illustrated in FIG. 8.

In the present embodiment, the warp of the substrate W illustrated in FIG. 7 is corrected using the characteristics illustrated in FIGS. 8, 9A, and 9B. Accordingly, the material film TF depending on the warped state and the warp amount of the substrate W is formed on the first face F1 of the substrate W to have film thicknesses differing in some portions.

For example, when the substrate W warps in a bowl shape (the center of the substrate W is closer to the lower electrode 60 than is the end portion of the substrate W), a silicon nitride film is formed on the first face F1 to apply an opposite stress to the substrate W. The silicon nitride film is formed, for example, by a plasma CVD method using a gas including SiH₄, NH₃, H₂, N₂, and Ar as the process gas. That is, when the center of the substrate W is closer to the lower electrode 60 than is the end portion of the substrate W due to the warp of the substrate W, it suffices that the gas introducing part 30 introduces the process gas including SiH₄, NH₃, H₂, N₂, and Ar into the chamber 10.

On the other hand, when the substrate W warps in a lobe shape (the end portion of the substrate W is closer to the lower electrode 60 than is the center of the substrate W), a silicon dioxide film is formed on the first face F1 to apply an opposite stress to the substrate W. The silicon dioxide film is formed, for example, by the plasma CVD method using a gas including SiH₄, N₂O, H₂, N₂, and Ar as the process gas. That is, when the end portion of the substrate W is closer to the lower electrode 60 than is the center of the substrate W due to warp of the substrate W, it suffices that the gas introducing part 30 introduces the process gas including SiH₄, N₂O, H₂, N₂, and Ar into the chamber 10.

For example, in the case of the substrate W warping in a bowl shape as illustrated in FIG. 7, the apparatus 1 deposits a silicon nitride film as the material film TF on the first face (the back surface) F1 of the substrate W. When the silicon nitride film is deposited on the first face F1 of the substrate W, the substrate W receives a stress to warp in a lobe shape inverse to the bowl shape as illustrated in FIG. 9A. In this case, it is preferable that the material film TF is formed relatively thick in the central portion of the substrate W in the X direction of FIG. 7 to extend in the Y direction in order to effectively correct the warp of the substrate W in the bowl shape in the Y direction. Furthermore, the material film TF may be formed to become gradually thinner as the distance from the center line of the substrate W in the X direction is larger. This enables the warp of the substrate W to be relatively intensely corrected in the vicinity of the center line of the substrate W in the X direction and to be more lightly corrected as the distance from the center line of the substrate W increases. As a result, the substrate W along the bowl shape can be effectively corrected so as to become close to a flat shape.

For example, the substrate W is mounted on the carrier ring 20 in the apparatus 1 to cause the extending direction (the Y direction) of the word lines WL on the substrate W to be substantially parallel to the extending direction of the regions Ra to Rg (that is, the partition plates 70). Next, the controller 100 increases the flow rate or the introducing time of the process gas to be introduced into the region Rd among the regions Ra to Rg, corresponding to the central portion of the substrate W, to be higher or longer than that in the regions Ra and Rg corresponding to the end portion of the substrate W. Accordingly, the material film TF is formed relatively thick in the central portion of the substrate W and is formed relatively thin in the end portion of the substrate W. Further, the controller 100 also causes the flow rate or the introducing time of the process gas to be introduced into associated regions Rb to Rf to be lower or shorter as the distance from the central portion of the substrate W increases. This enables the material film TF to be relatively thick in the central portion of the substrate W and to be gradually thinned as the distance to the end portion of the substrate W decreases. Accordingly, the substrate W along the bowl shape can be corrected to become close to a flat shape.

In this way, the apparatus 1 can change the thickness of the material film TF on the first face F1 of the substrate W from the center to the end portion by forming the material film TF in a state in which the extending direction of the regions Ra to Rg (that is, the extending direction of the partition plates 70) is substantially parallel to the extending direction of the word lines WL. Accordingly, warp of the substrate W can be effectively corrected.

In the embodiment described above, the substrate W warps in a bowl shape and a silicon nitride film is used as an example of the material film TF. On the other hand, when the substrate W inversely warps in a lobe shape, a silicon dioxide film is used as an example of the material film TF. That is, the apparatus 1 can correct warp of the substrate W not only when the substrate W warps in a bowl shape but also when the substrate W warps in a lobe shape.

Therefore, the apparatus 1 corrects warp of the substrate W to be flattened, or reduces the warp amount to enable transporting of the substrate W in the semiconductor manufacturing process. Suppression of warp of the substrate W leads to improvement in the quality and the yield ratio of semiconductor devices.

### (Second Embodiment)

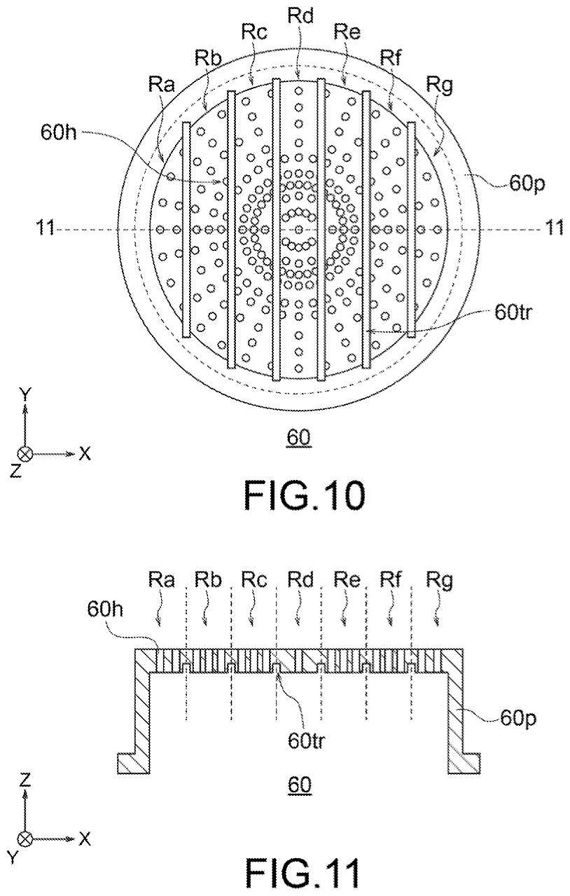

FIG. 10 is a plan view illustrating a configuration example of the lower electrode 60 according to a second embodiment. FIG. 11 is a sectional view illustrating a configuration example of the lower electrode 60 according to the second embodiment. FIG. 11 illustrates a cross section along a line 11-11 in FIG. 10.

The lower electrode 60 has a substantially circular shape having a diameter equal to or larger than the diameter of the substrate W as viewed from the direction (the Z direction) perpendicular to the first face F1 of the substrate W. Therefore, when the substrate W is mounted on the carrier ring 20, the lower electrode 60 overlaps with the substrate W and the outer edge of the lower electrode 60 is positioned on an outer side than the outer edge of the substrate W as viewed from the Z direction. Accordingly, the holes 60h of the lower electrode 60 are dispersedly arranged all over the substrate W. In the second embodiment, the holes 60h are arranged radially from the center of the lower electrode 60. The rest of the configurations of the lower electrode 60 according to the second embodiment may be identical to the configurations of the lower electrode 60 according to the first embodiment.

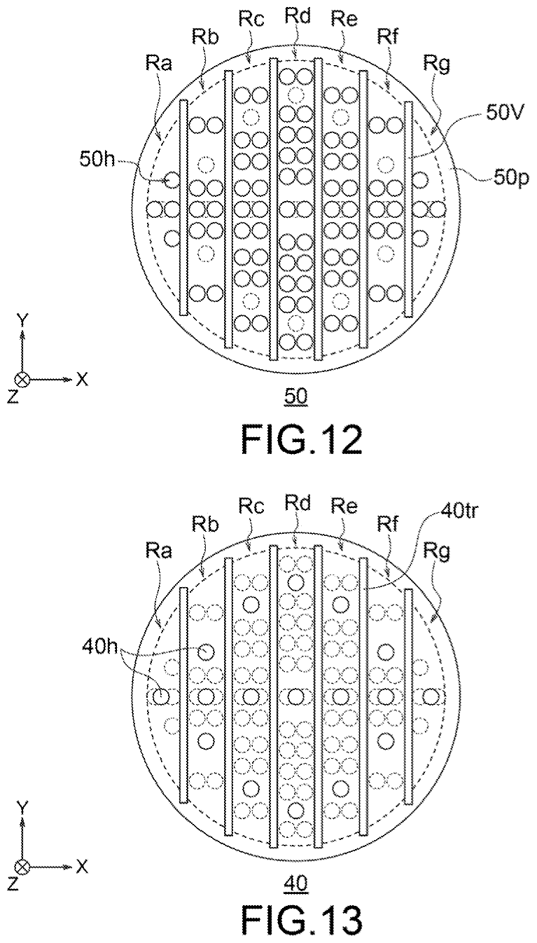

FIG. 12 is a plan view illustrating a configuration example of the second gas dispersing plate 50 according to the second embodiment.

The second gas dispersing plate 50 has a substantially circular shape having a diameter equal to or larger than the diameter of the substrate W as viewed from the direction (the Z direction) perpendicular to the first face F1 of the substrate W, similarly to the lower electrode 60. Therefore, when the substrate W is mounted on the carrier ring 20, the second gas dispersing plate 50 overlaps with the substrate W and the outer edge of the second gas dispersing plate 50 is positioned on an outer side than the outer edge of the substrate W as viewed from the Z direction. The holes 50h of the second gas dispersing plate 50 are dispersedly arranged all over the substrate W. The rest of the configurations of the second gas dispersing plate 50 according to the second embodiment may be identical to the configurations of the second gas dispersing plate 50 according to the first embodiment.

FIG. 13 is a plan view illustrating a configuration example of the first gas dispersing plate 40 according to the second embodiment.

The first gas dispersing plate 40 has a substantially circular shape having a diameter equal to or larger than the diameter of the substrate W as viewed from the direction (the Z direction) perpendicular to the first face F1 of the substrate W, similarly to the lower electrode 60. Therefore, when the substrate W is mounted on the carrier ring 20, the first gas dispersing plate 40 overlaps with the substrate W and the outer edge of the first gas dispersing plate 40 is positioned on an outer side than the outer edge of the substrate W as viewed from the Z direction. The holes 40h of the first gas dispersing plate 40 are dispersedly arranged all over the substrate W. The rest of the configurations of the first gas dispersing plate 40 according to the second embodiment may be identical to the configurations of the first gas dispersing plate 40 according to the first embodiment.

The rest of the configurations of the second embodiment may be identical to the corresponding configurations of the first embodiment. Therefore, even when the first gas dispersing plate 40, the second gas dispersing plate 50, and the lower electrode 60 have a substantially circular shape, the second embodiment can achieve effects identical to those of the first embodiment.

### (Third Embodiment)

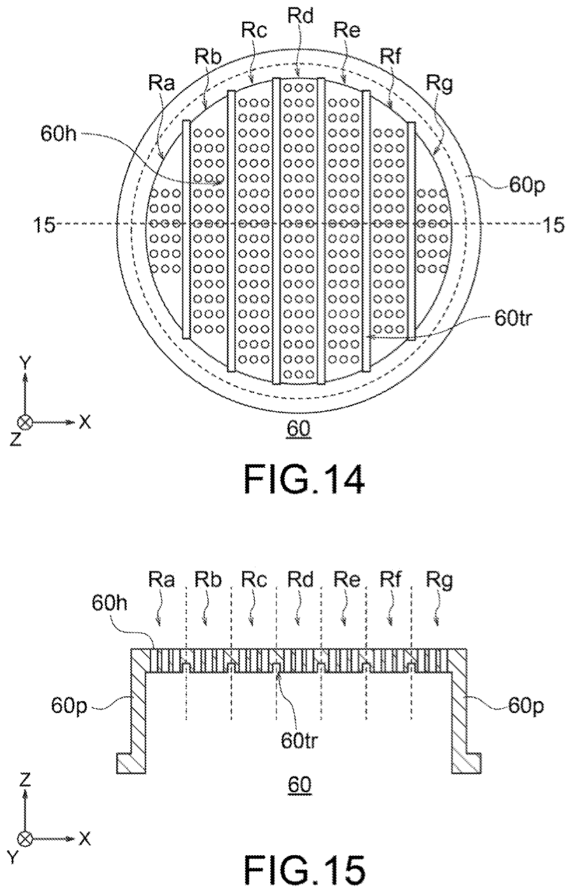

FIG. 14 is a plan view illustrating a configuration example of the lower electrode 60 according to a third embodiment. FIG. 15 is a sectional view illustrating the configuration example of the lower electrode 60 according to the third embodiment. FIG. 15 illustrates a cross section along a line 15-15 in FIG. 14.

The lower electrode 60 according to the third embodiment is the same as the lower electrode 60 according to the second embodiment in having a substantially circular shape having a diameter equal to or larger than the diameter of the substrate W as viewed from the direction (the Z direction) perpendicular to the first face F1 of the substrate W. Therefore, when the substrate W is mounted on the carrier ring 20, the lower electrode 60 overlaps with the substrate W and the outer edge of the lower electrode 60 is positioned on an outer side than the outer edge of the substrate W as viewed from the Z direction. Accordingly, the holes 60h of the lower electrode 60 are dispersedly arranged all over the substrate W.

On the other hand, the holes 60h of the lower electrode 60 according to the third embodiment are arrayed in a matrix in each of the regions Ra to Rg of the lower electrode 60. In this way, the holes 60h may be arrayed in a matrix in the substantially circular lower electrode 60.

The rest of the configurations of the third embodiment may be identical to the corresponding configurations of the second embodiment. Therefore, the third embodiment can achieve effects identical to those of the second embodiment.

In the embodiments described above, all the partition plates 70 extend substantially parallel to the Y direction. Meanwhile, although not illustrated in the drawings, another partition plate or a plurality of other partition plates may be provided for reinforcement in a direction substantially orthogonal to the partition plates 70 in faces of the lower electrode 60 and the first and second gas dispersing plates 40 and 50. Even when such other partition plates are added, the effects of the present embodiment are not lost.

Although the second gas dispersing plate 50 is provided in the embodiments described above, the second gas dispersing plate 50 does not need to be provided when the process gas is sufficiently dispersed in each of the regions Ra to Rg.

### (Fourth Embodiment)

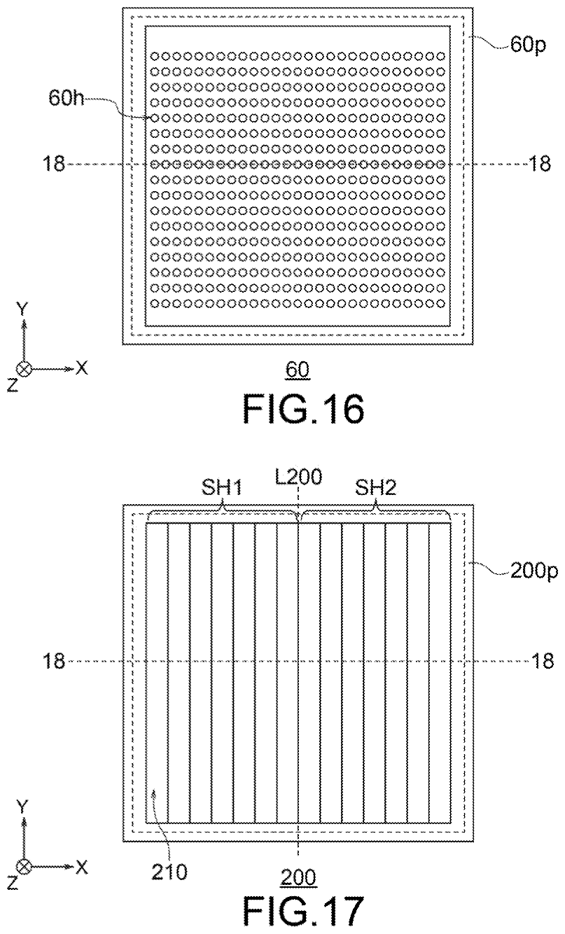

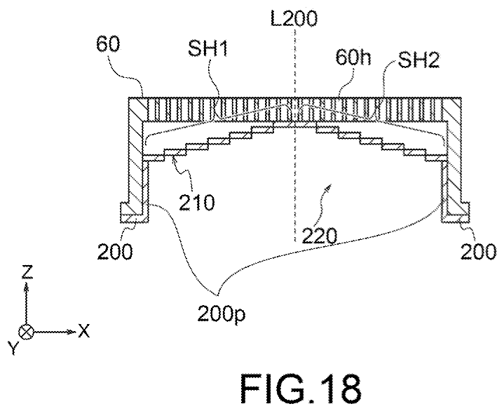

FIG. 16 is a plan view illustrating a configuration example of the lower electrode 60 according to a fourth embodiment. FIG. 17 is a plan view illustrating a configuration example of a mask part 200 attached to the lower electrode 60. FIG. 18 is a sectional view illustrating a configuration example of the lower electrode 60 and the mask part 200. FIG. 18 corresponds to a cross section along a line 18-18 in FIGS. 16 and 17.

The partition plates 70 are not provided for the lower electrode 60 and the first and second gas dispersing plates 40 and 50 according to the fourth embodiment, and the regions Ra to Rg are not formed. Therefore, the lower electrode 60 does not include the trenches 60tr. Although not illustrated in the drawings, the through slots 50v of the second gas dispersing plate 50 and the trenches 40tr of the first gas dispersing plate 40 are not provided, either. The rest of the configurations of the lower electrode 60 and the first and second gas dispersing plates 40 and 50 may be identical to those of the first embodiment. The lower electrode 60 and the mask part 200 each have a substantially quadrangular shape having four sides equal to or larger than the diameter of the substrate W in a planar view as viewed from the Z direction, similarly to the lower electrode 60 according to the first embodiment.

On the other hand, in the fourth embodiment, the mask part 200 is attached instead of the partition plates 70 to the lower electrode 60.

The mask part 200 is provided between the lower electrode 60 and the second gas dispersing plate 50. In a case in which the second gas dispersing plate 50 is not provided, the mask part 200 is provided between the lower electrode 60 and the first gas dispersing plate 40. The mask part 200 masks the holes 60h of the lower electrode 60 to disconnect the holes 60h from the first or second gas dispersing plate 40 or 50 in a space between the lower electrode 60 and the first or second gas dispersing plate 40 or 50. For example, any of materials such as aluminum, stainless steel, and ceramics is used for the mask part 200.

The mask part 200 includes shutter parts SH1 and SH2 and a support post 200p. Each of the shutter parts SH1 and SH2 is constituted of a plurality of plate-like members 210 extending in the Y direction as illustrated in FIGS. 17 and 18. The plate-like members 210 are arrayed in the X direction with no space therebetween, whereby the plate-like members 210 can cover all over the lower electrode 60. Accordingly, the mask part 200 can screen the lower electrode 60 from the first or second gas dispersing plate 40 or 50 to suppress the process gas from being introduced into the chamber 10 through the holes 60h. FIGS. 17 and 18 illustrate a state in which the mask part 200 covers all over the lower electrode 60 and the process gas is blocked. For example, any of materials such as aluminum, stainless steel, and ceramics is used for the shutter parts SH1 and SH2.

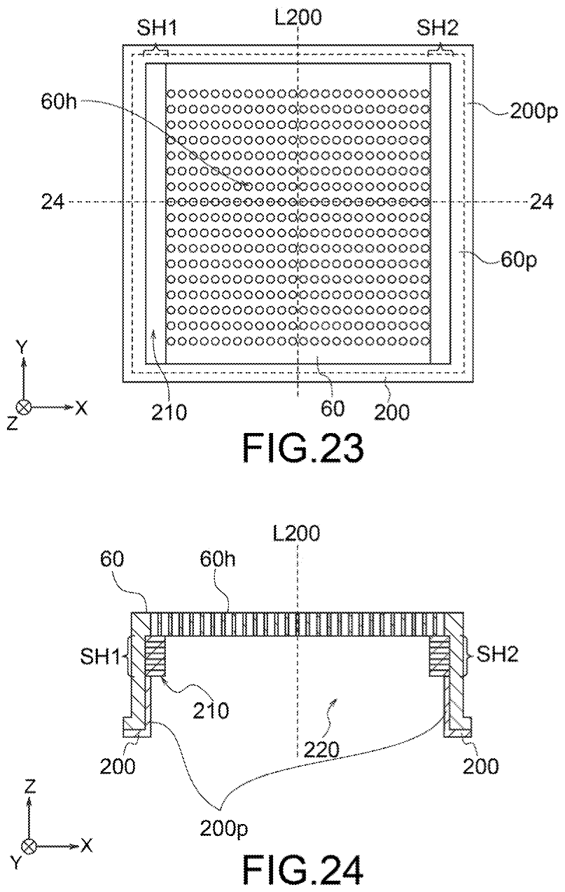

The plate-like members 210 are configured to be foldable from a center line L200 of the lower electrode 60 and the mask part 200 toward both sides of the lower electrode 60 in ±X directions. The shutter part SH1 is openable in the −X direction (in a substantially orthogonal direction to the center line L200) from the center line L200 toward one side of the lower electrode 60. The shutter part SH2 is openable in the +X direction (in the opposite direction to the shutter part SH1) from the center line L200 toward the opposite side of the lower electrode 60 to the said one side. When the plate-like members 210 are folded, the plate-like members 210 of the shutter part SH1 are housed along one side of the lower electrode 60 to overlap with each other and the plate-like members 210 of the shutter part SH2 are housed along the other side of the lower electrode 60 to overlap with each other as viewed from the Z direction (see FIGS. 23 and 24).

As illustrated in FIG. 18, ones of the plate-like members 210, which are closest to the center line L200 of the lower electrode 60, are in contact with the back surface of the lower electrode 60 and are configured to slide in the ±X directions on the back surface of the lower electrode 60. In a state in which the shutter parts SH1 and SH2 are closed, the plate-like members 210 are away from the lower electrode 60 in a staircase manner as the distance from the center line L200 in the ±X directions increases.

The mask part 200 can expose the holes 60h of the lower electrode 60 to the first or second gas dispersing plate 40 or 50 by opening the shutter part SH1 in the −X direction from the center line L200 and opening the shutter part SH2 in the +X direction from the center line L200. At this time, the plate-like members 210 closest to the center line L200 of the lower electrode 60 move while being in contact with the back surface of the lower electrode 60 (see FIGS. 18, 20, 22, and 24). While the holes 60h in a region of the lower electrode 60 covered by the mask part 200 are screened from the first or second gas dispersing plate 40 or 50, the holes 60h in a region of the lower electrode 60 exposed from the mask part 200 are exposed to the first or second gas dispersing plate 40 or 50. The process gas is supplied from the exposed holes 60h not screened by the mask part 200 to the substrate W.

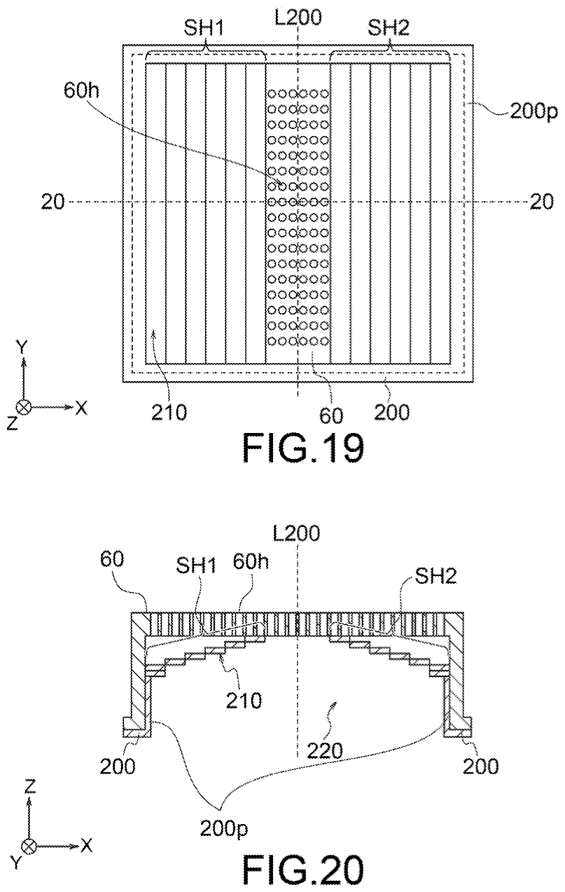

For example, FIGS. 19 and 20 are diagrams illustrating a state in which the mask part 200 opens some of the holes 60h of the lower electrode 60 in a central portion (for example, at an opening degree of about 25%). FIG. 20 is a sectional view along a line 20-20 in FIG. 19. In this case, the shutter parts SH1 and SH2 are opened from the central line L200 of the lower electrode 60 toward the both sides (in the ±X directions) and expose some of the holes 60h in the central portion to a space 220. Other holes 60h are covered by the shutter parts SH1 and SH2 and are screened from the space 220 (that is, the first and second gas dispersing plates 40 and 50). In this case, since the plate-like members 210 closest to the center line L200 are kept in contact with the back surface of the lower electrode 60 at that time, the process gas in the space 220 does not directly reach the holes 60h covered by the shutter parts SH1 and SH2.

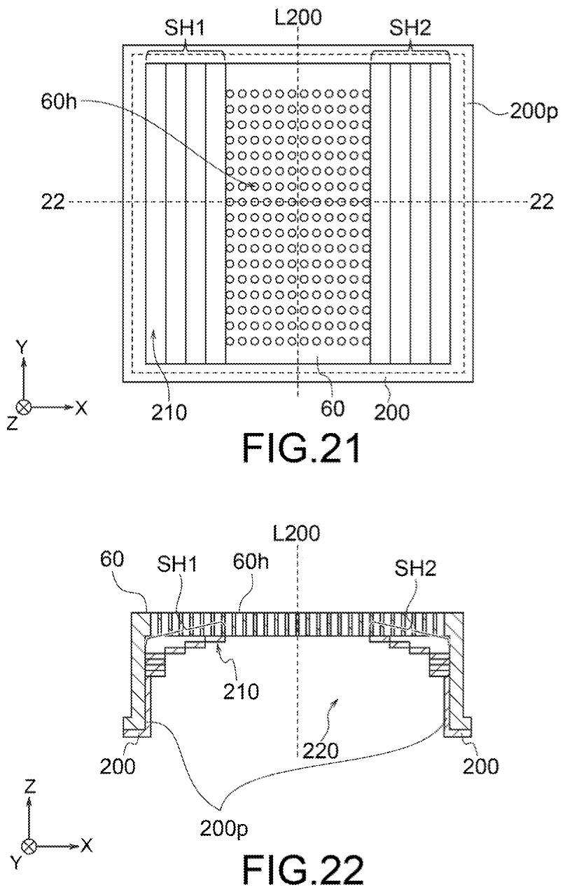

FIGS. 21 and 22 are diagrams illustrating a state in which the mask part 200 opens some of the holes 60h of the lower electrode 60 in a central portion (for example, at an opening degree of about 50%). FIG. 22 is a sectional view along a line 22-22 in FIG. 21. In this case, the shutter parts SH1 and SH2 are further opened from the center line L200 of the lower electrode 60 toward the both sides (in the ±X directions) and expose about a half of the holes 60h to the space 220. Other holes 60h are covered by the shutter parts SH1 and SH2 and are screened from the space 220 (that is, the first and second gas dispersing plates 40 and 50). Also in this case, the plate-like members 210 closest to the center line L200 are kept in contact with the back surface of the lower electrode 60 at that time, the process gas in the space 220 does not directly reach the holes 60h covered by the shutter parts SH1 and SH2.

FIGS. 23 and 24 are diagrams illustrating a state in which the mask part 200 opens all the holes 60h of the lower electrode 60. FIG. 24 is a sectional view along a line 24-24 in FIG. 23. The plate-like members 210 of the shutter parts SH1 and SH2 are folded at the both sides of the lower electrode 60, respectively, to overlap with each other as viewed from the Z direction. In this case, the shutter parts SH1 and SH2 are opened to the both sides (in the ±X directions) from the center line L200 of the lower electrode 60 and expose all the holes 60h to the space 220.

In this way, the mask part 200 can change the area of the lower electrode 60 exposed on the both sides of the center line L200 according to the opening degree of the shutter parts SH1 and SH2. The opening degree of the shutter parts SH1 and SH2 is determined in a state in which the ends of the plate-like members 210 closest to the center line L200 are in contact with the back surface of the lower electrode 60. The gas introducing part 30 then flows the process gas in the state in which the ends of the plate-like members 210 are in contact with the back surface of the lower electrode 60. Forming the material film TF using the mask part 200 described above enables the material film TF partially differing in the thickness to be formed on the first face F1 of the substrate W. For example, the material film TF is first deposited on the substrate W at the opening degree illustrated in FIGS. 19 and 20 (for example, the opening degree of about 25%), the material film TF is subsequently deposited on the substrate W at the opening degree illustrated in FIGS. 21 and 22 (for example, the opening degree of about 50%), and the material film TF is further deposited on the substrate W at the opening degree illustrated in FIGS. 23 and 24 (for example, the opening degree of about 100%). Accordingly, the material film TF is formed relatively thick in the central portion of the substrate W and is formed relatively thinner toward the end part. As a result, the fourth embodiment also can appropriately correct the warp of the substrate W similarly to the first embodiment.

### (Fifth Embodiment)

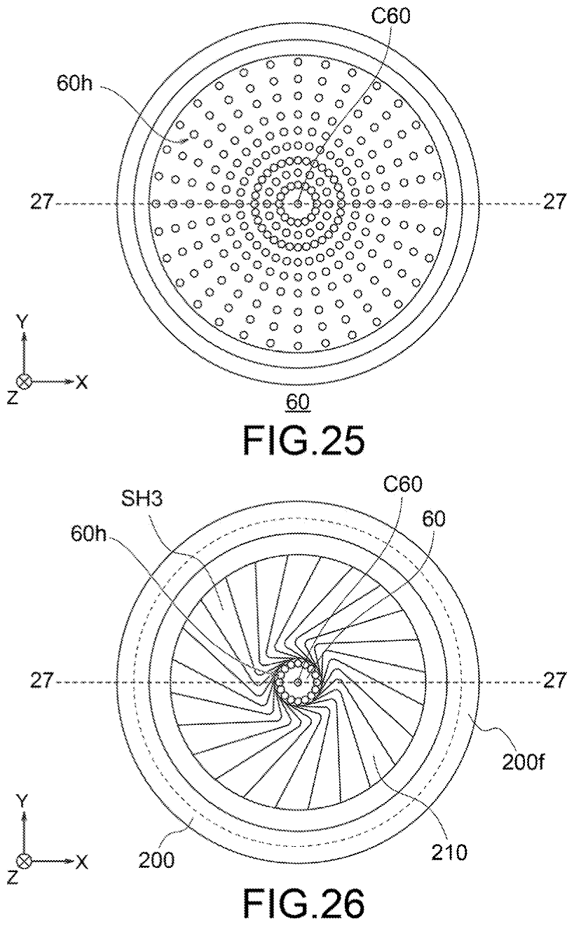

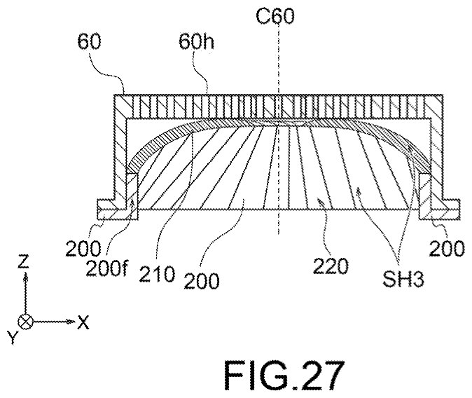

FIG. 25 is a plan view illustrating a configuration example of the lower electrode 60 according to a fifth embodiment. FIG. 26 is a plan view illustrating a configuration example of the mask part 200 attached to the lower electrode 60. FIG. 27 is a sectional view illustrating a configuration example of the lower electrode 60 and the mask part 200. FIG. 27 corresponds to a cross section along a line 27-27 in FIGS. 25 and 26.

The partition plates 70 are not provided for the lower electrode 60 and the first and second gas dispersing plates 40 and 50 according to the fifth embodiment, similarly to the fourth embodiment. Also in the fifth embodiment, the mask part 200 is attached instead of the partition plates 70 to the lower electrode 60. In the fifth embodiment, the lower electrode 60 has a substantially circular shape in a planar view as viewed from the Z direction. The lower electrode 60 and the mask part 200 each have a substantially circular shape having a diameter equal to or larger than the diameter of the substrate W in the planar view as viewed from the Z direction, similarly to the lower electrode 60 according to the second embodiment.

The mask part 200 is provided between the lower electrode 60 and the second gas dispersing plate 50. In a case in which the second gas dispersing plate 50 is not provided, the mask part 200 is provided between the lower electrode 60 and the first gas dispersing plate 40. The mask part 200 masks the holes 60h of the lower electrode 60 to disconnect the holes 60h from the first or second gas dispersing plate 40 or 50 in the space between the lower electrode 60 and the first or second gas dispersing plate 40 or 50. For example, a material such as aluminum, stainless steel, or ceramics is used for the mask part 200.

The mask part 200 includes a shutter part SH3 and a frame 200f. The shutter part SH3 is constituted of a plurality of plate-like members 210 arrayed in a circular shape as illustrated in FIGS. 26 and 27. The plate-like members 210 are arrayed in a circular manner around a center C60 of the lower electrode 60 with no space therebetween, whereby the plate-like members 210 can cover all over the lower electrode 60. Accordingly, the mask part 200 can screen the lower electrode 60 from the first or second gas dispersing plate 40 or 50 to suppress the process gas from being introduced into the chamber 10 through the holes 60h. FIGS. 26 and 27 illustrate a state in which the mask part 200 exposes the holes 60h in a central portion of the lower electrode 60 and shields the holes 60h in other regions. The shutter part SH3 opens at least the holes 60h in the central portion of the lower electrode 60 among the holes 60h to the space 220. For example, any of materials such as aluminum, stainless steel, and ceramics is used for the shutter part SH3.

As illustrated in FIG. 27, end portions of the plate-like members 210 on the side of the center C60 are in contact with the back surface of the lower electrode 60 and are configured to slide on the back surface of the lower electrode 60. The plate-like members 210 are configured to be folded while turning around the center C60. A contact portion between the plate-like members 210 and the lower electrode 60 moves from the center C60 of the lower electrode 60 toward the outer periphery when the plate-like members 210 are folded to be away from the center C60.

The mask part 200 can expose the holes 60 in the central portion of the lower electrode 60 and in the vicinity thereof to the first or second gas dispersing plate 40 or 50 by opening the shutter part SH3. At this time, since the end portions of the plate-like members 210 close to the center C60 of the lower electrode 60 are kept in contact with the back surface of the lower electrode 60, the holes 60h are shielded from the first or second gas dispersing plate 40 or 50 in a region of the lower electrode 60 covered by the mask part 200. The process gas is supplied to the substrate W from the exposed holes 60h not shielded by the mask part 200.

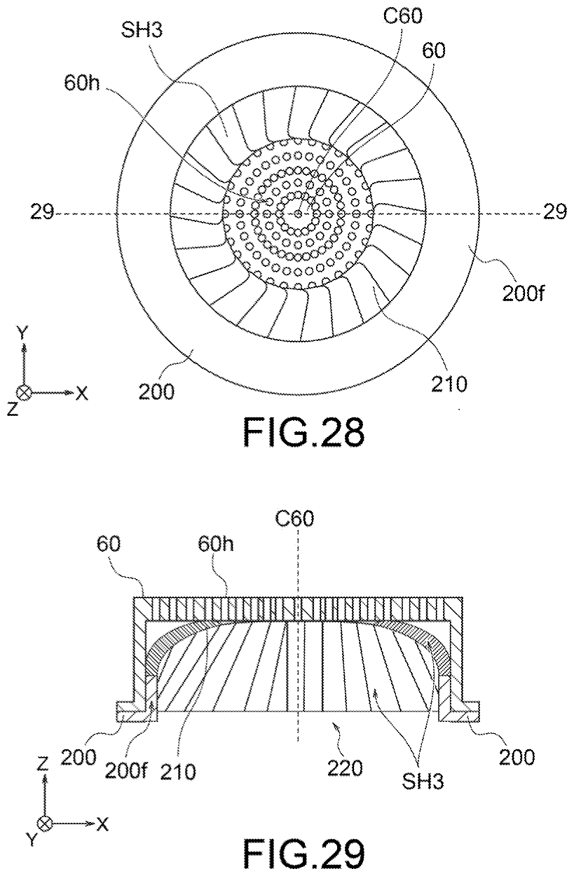

For example, FIGS. 28 and 29 are diagrams illustrating a state in which the mask part 200 opens some of the holes 60h of the lower electrode 60. FIG. 29 is a sectional view along a line 29-29 in FIG. 28. In this case, the shutter part SH3 is opened outward from the center C60 of the lower electrode 60 and exposes some of the holes 60h to the space 220. Other holes 60h are covered by the shutter SH3 and are shielded from the space 220 (that is, the first and second gas dispersing plates 40 and 50). Since the end portions of the plate-like members 210 close to the center C60 keep the state being in contact with the back surface of the lower electrode 60, the process gas in the space 220 does not directly reach the holes 60h covered by the shutter part SH3.

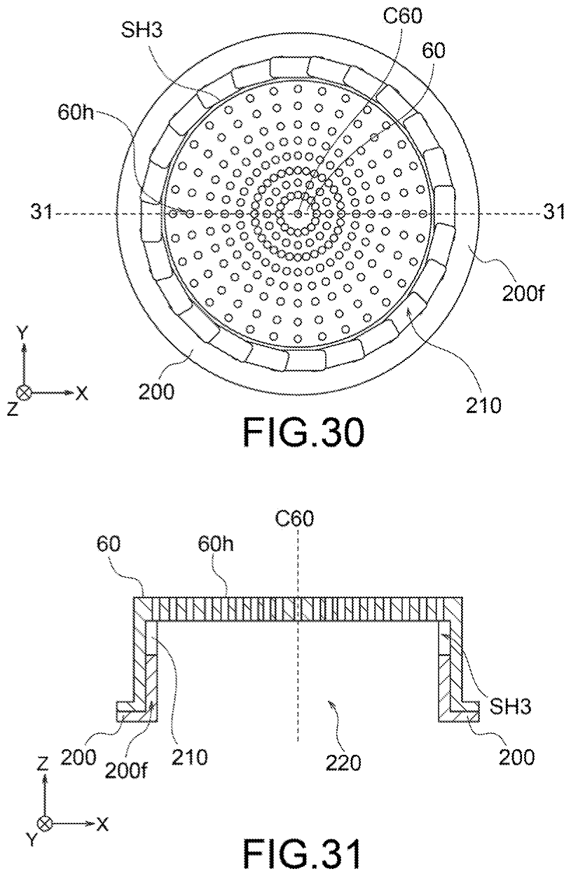

FIGS. 30 and 31 are diagrams illustrating a state in which the mask part 200 opens all the holes 60h of the lower electrode 60. FIG. 31 is a sectional view along a line 31-31 in FIG. 30. The plate-like members 210 of the shutter part SH3 are folded on the frame 200f of the lower electrode 60 to overlap with each other as viewed from the Z direction. In this case, the shutter part SH3 exposes all the holes 60h of the lower electrode 60 to the space 220.

In this way, the mask part 200 includes a substantially circular shutter part SH3 that is openable from the center of the lower electrode 60 toward the outer edge of the lower electrode 60. The mask part 200 can change the area of the lower electrode 60 exposed from the center C60 toward the outer edge according to the opening degree of the shutter part SH3. The opening degree of the shutter part SH3 is determined in a state in which the ends of the plate-like member 210 close to the center C60 are in contact with the back surface of the lower electrode 60. The gas introducing part 30 then flows the process gas in the state in which the ends of the plate-like members 210 are in contact with the back surface of the lower electrode 60. Forming the material film TF using the mask part 200 described above enables the material film TF partially differing in the thickness to be formed on the first face F1 of the substrate W. For example, the material film TF is first deposited on the substrate W at the opening degree illustrated in FIGS. 26 and 27, the material film TF is subsequently deposited on the substrate W at the opening degree illustrated in FIGS. 28 and 29, and the material film TF is further deposited on the substrate W at the opening degree illustrated in FIGS. 30 and 31. Accordingly, the material film TF is formed relatively thick in the central portion of the substrate W and is formed relatively thinner toward the outer edge portion. As a result, the apparatus 1 according to the fifth embodiment can appropriately correct the substrate W by formation of the material film TF even when the substrate W warps in a bowl shape or a lobe shape from the center to the outer edge in both the X direction and the Y direction. The rest of the configurations of the fifth embodiment may be identical to those of the second embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a processing container;
a holder provided in the processing container and capable of holding a substrate;
a gas introducing part provided on a side of a first face of the substrate and configured to introduce a process gas into the processing container;
a first gas supply plate provided between the substrate and the gas introducing part and having a plurality of first holes allowing the process gas to pass;
a first electrode provided between the substrate and the first gas supply plate and having a plurality of second holes supplying the process gas to the first face of the substrate;
a second electrode provided on a side of a second face of the substrate opposite to the first face and applying an electric field to the process gas between the first and second electrodes; and
a plurality of partitions provided between the first electrode and the first gas supply plate, extending substantially linearly in a first direction substantially parallel to the first face, and dividing a space between the first electrode and the first gas supply plate into a plurality of regions.

2. The apparatus of claim 1, wherein the partitions extend substantially in parallel to each other in the first direction.

3. The apparatus of claim 1, wherein
one ends of the partitions are in contact with the first gas supply plate;
another ends of the partitions are in contact with the first electrode, and
the partitions separate the process gas in the regions from each other.

4. The apparatus of claim 1, wherein the gas introducing part comprises a plurality of inlets introducing the process gas into the regions, respectively.

5. The apparatus of claim 4, wherein
the process gas from the inlets of the gas introducing part is introduced to associated ones of the regions, respectively, through associated ones of the first holes of the first gas supply plate, and
the process gas respectively introduced into the regions is supplied to the first face of the substrate through associated ones of the second holes of the first electrode.

6. The apparatus of claim 1, further comprising a controller configured to control a flow rate or an introducing time of the process gas to be introduced into each of the regions.

7. The apparatus of claim 6, wherein the controller increases the flow rate or the introducing time of the process gas to be introduced into a first region among the regions, corresponding to a central portion of the substrate, to be higher or longer than that in a second region corresponding to an end portion of the substrate.

8. The apparatus of claim 1, wherein
the substrate comprises lines of a conductive material on the second face, and
the first direction in which the partitions extend is substantially parallel to an extending direction of the lines.

9. The apparatus of claim 1, wherein the second holes are arrayed in a matrix to correspond to each of the regions on the first electrode.

10. The apparatus of claim 1, wherein the first electrode has a substantially quadrangular shape having four sides equal to or larger than a diameter of the substrate as viewed from a perpendicular direction to the first face.

11. The apparatus of claim 1, wherein the first electrode has a substantially circular shape having a diameter equal to or larger than a diameter of the substrate as viewed from a perpendicular direction to the first face.

12. The apparatus of claim 11, wherein the second holes are arrayed on the first electrode radially from a center of the first electrode.

13. The apparatus of claim 1, wherein the gas introducing part introduces a gas including SiH₄ and N₂O as the process gas into the processing container when a center of the substrate held by the holder is farther from the first electrode than is an end portion of the substrate.

14. The apparatus of claim 1, wherein the gas introducing part introduces a gas including SiH₄ and NH₃ as the process gas into the processing container when a center of the substrate held by the holder is closer to the first electrode than is an end portion of the substrate.

15. The apparatus of claim 1, wherein the second electrode has a plurality of third holes supplying an inert gas to the second face of the substrate.

16. A semiconductor manufacturing apparatus comprising:
a processing container;
a holder provided in the processing container and capable of holding a substrate;
a gas introducing part provided on a side of a first face of the substrate and configured to introduce a process gas into the processing container;
a first gas supply plate provided between the substrate and the gas introducing part and having a plurality of first holes allowing the process gas to pass;
a first electrode provided between the substrate and the first gas supply plate and having a plurality of second holes supplying the process gas to the first face of the substrate;
a second electrode provided on a side of a second face of the substrate opposite to the first face and applying an electric field to the process gas between the first and second electrodes; and
a mask part provided between the first electrode and the first gas supply plate and disconnecting at least second holes located in a portion other than a central portion of the first electrode among the second holes from the first gas supply plate in a space between the first electrode and the first gas supply plate.

17. The apparatus of claim 16, wherein
the first electrode and the mask part each have a substantially quadrangular shape having four sides equal to or larger than a diameter of the substrate as viewed from a perpendicular direction to the first face, and
the mask part comprises a first shutter part openable from a center line of the first electrode toward a first side of the first electrode, and a second shutter part openable from the center line toward an opposite side of the first electrode to the first side.

18. The apparatus of claim 17, wherein the first and second shutter parts open at least second holes located in the central portion of the first electrode among the second holes to the space between the first electrode and the first gas supply plate.

19. The apparatus of claim 16, wherein
the first electrode and the mask part each have a substantially circular shape having a diameter equal to or larger than a diameter of the substrate as viewed from a perpendicular direction to the first face, and
the mask part comprises a third shutter part openable from a center of the first electrode toward an outer edge of the first electrode.

20. The apparatus of claim 19, wherein the third shutter part opens at least second holes located in the central portion of the first electrode among the second holes to the space between the first electrode and the first gas supply plate.
